(19) United States
(12) Patent Application Publication
(10) Pub. No.: US 2026/0333829 A1
(43) Pub. Date: Oct. 22, 2026

(54) SOURCE/DRAIN EPITAXIAL PROFILES AND METHODS OF FORMING

(71) Applicant: Taiwan Semiconductor Manufacturing Co., Ltd., Hsinchu (TW)

(72) Inventors: Ching Chang, Hsinchu (TW); Chien-I Kuo, Zhubei (TW); Ming-Hua Yu, Hsinchu (TW)

(21) Appl. No.: 19/184,503

(22) Filed: Apr. 21, 2025

(51) Int. Cl. H10D 84/01; H10D 62/40; H10D 84/83

(52) U.S. Cl. CPC H10D 84/013; H10D 62/405; H10D 84/832

(57) ABSTRACT

In some embodiments, a device including a nanostructure stack on a substrate, the substrate having a (110) crystalline orientation; and a gate structure on a channel portion of the nanostructure stack. The device may further include source/drain regions on opposing sides of the channel portion of the nanostructure stack, wherein a width of the source/drain regions in a direction perpendicular to the channel portion length is between source/drain sidewalls having a sidewall face along a (001) plane.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 10A, 10B, 11A, 11B, 11C, 12A, 12B, 12C, 12D, 12E, 13A, 13B, 13C, 14A, 14B, 15A, 15B, 16A, 16B, 17A, 17B, 18A, 18B, 18C, 19A, 19B, 19C, 20A, 20B, 20C, 21A, 21B, and 21C are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the methods and structures of the present disclosure can control the profile of epitaxially deposited materials that may be employed for source/drain regions of a semiconductor device. In some embodiments, the methods and structures of the present disclosure can control the shape of the profile for epitaxially deposited material by utilizing a (110) substrate to provide the orientation for the deposition surfaces on which the epitaxial material is formed. Field effect transistors formed on a (100) substrate can have an inadequate p-type field effect transistor (PFET) merge window that results {111} facet intersection. In some embodiments, the methods and structures of the present disclosure can prevent merging of the epitaxial material for the source/drain regions by controlling the sidewall crystal planes of the epitaxial material for the source/drain regions to be vertically flat or slightly tilted. For example, in some embodiments, the PFET-to-PFET distance of the epitaxially deposited material for the source/drain regions can be controlled by configuring the epitaxial material for the source/drain regions to have sidewalls with a (001) crystal plane.

Embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the nano-FETs.

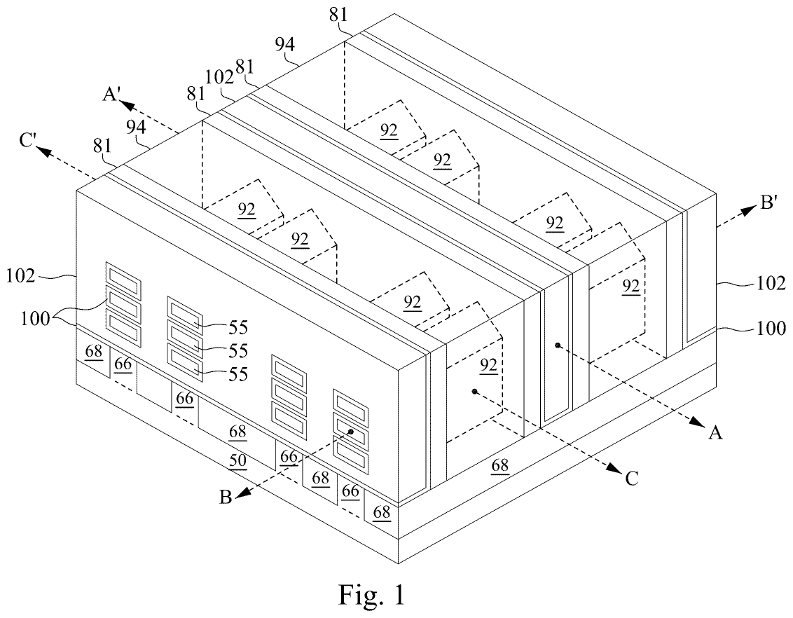

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 55 (e.g., nanosheets, nanowires, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions and the fins 66. For example, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portions extending between the neighboring STI regions 68.

In some embodiments, the substrate 50 has a (110) crystalline orientation. A “(110) substrate” refers to a material used as a base surface in manufacturing, where the crystal lattice of the material is oriented along the (110) crystallographic plane, meaning the atoms on the surface are arranged in a specific pattern defined by these Miller indices. A (110) substrate with p-type doping can exhibit improved hole mobility compared to a (100) substrate, potentially leading to better performance in certain semiconductor devices, particularly when dealing with scaled transistors, e.g., p-type semiconductor devices, such as p-type field effect transistors (PFET), due to the unique crystallographic arrangement of atoms on the (110) plane, which can enhance carrier transport for holes. In some embodiments, the advantage for carrier mobility that is exhibited for holes on (110) substrates may be less pronounced compared to n-type devices on (110) substrates, in which the majority carrier for n-type devices are electrons.

Gate dielectric layers 100 are over top surfaces of the fins 66 and along top surfaces, sidewalls, and bottom surfaces of the nanostructures 55. Gate electrodes 102 are over the gate dielectric layers 100, and gate spacers 81 are disposed along sidewalls of the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context. One or more dielectric layers (e.g., interlayer dielectric (ILD) 96) may be formed over the epitaxial source/drain regions 92 between the gate dielectric layers 100/gate electrodes 102.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

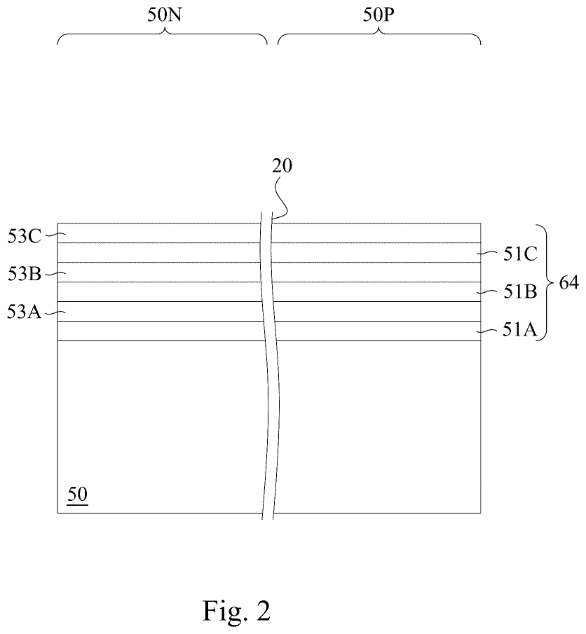

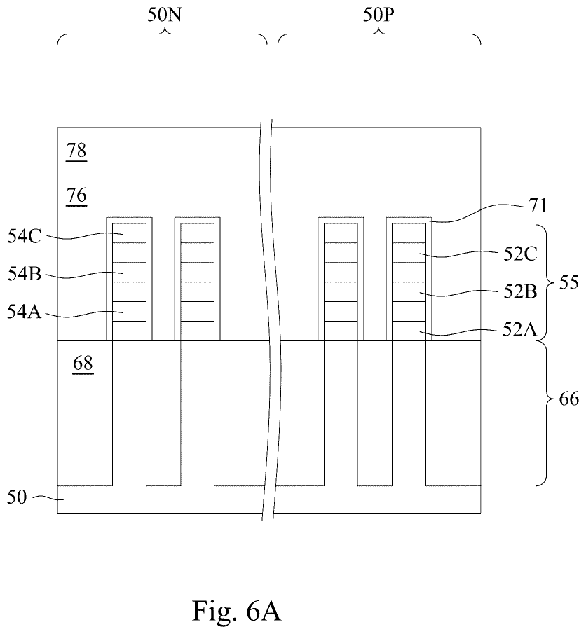

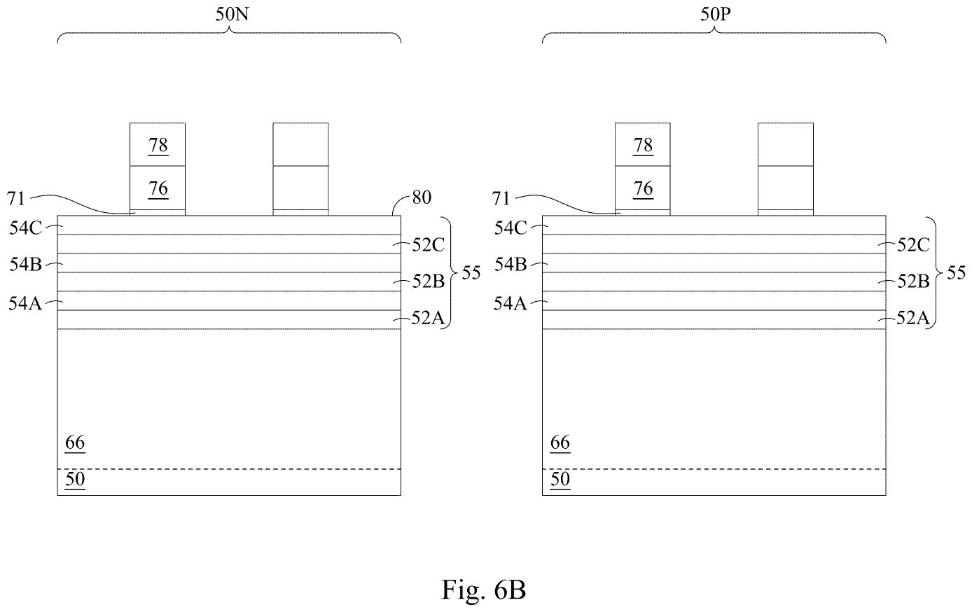

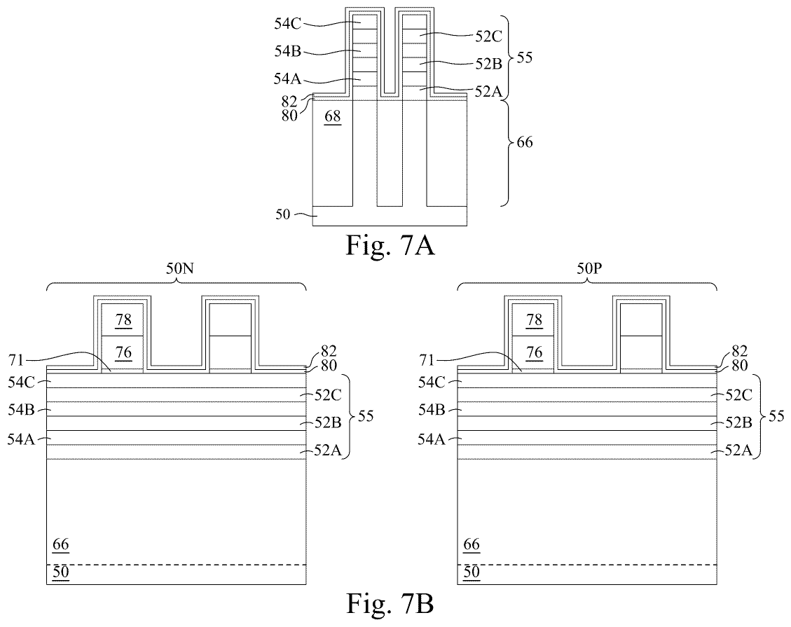

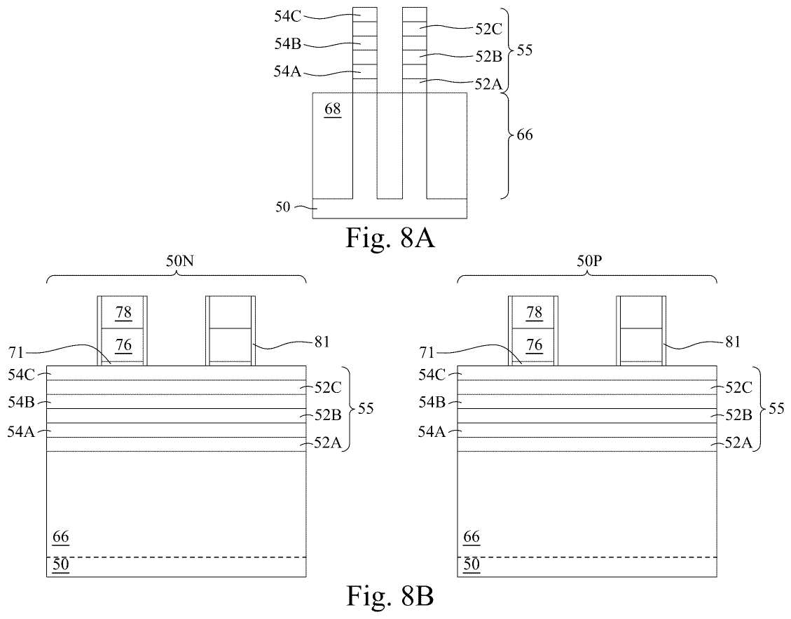

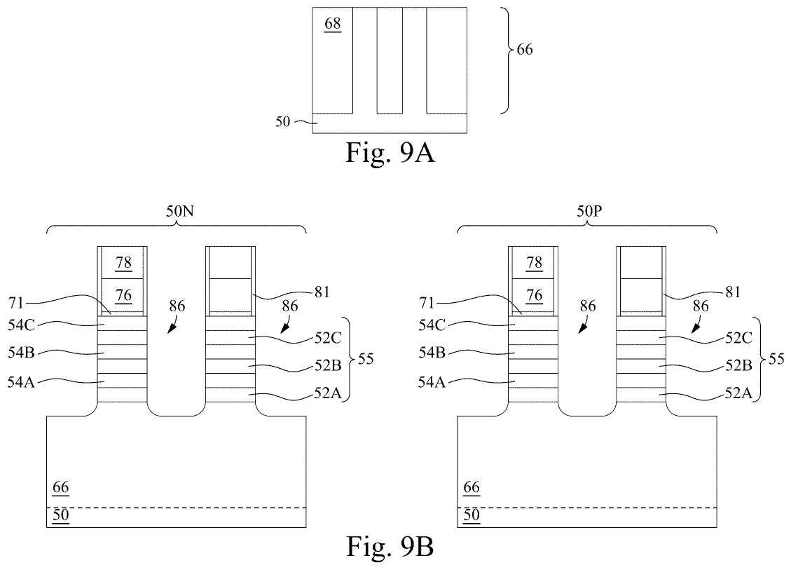

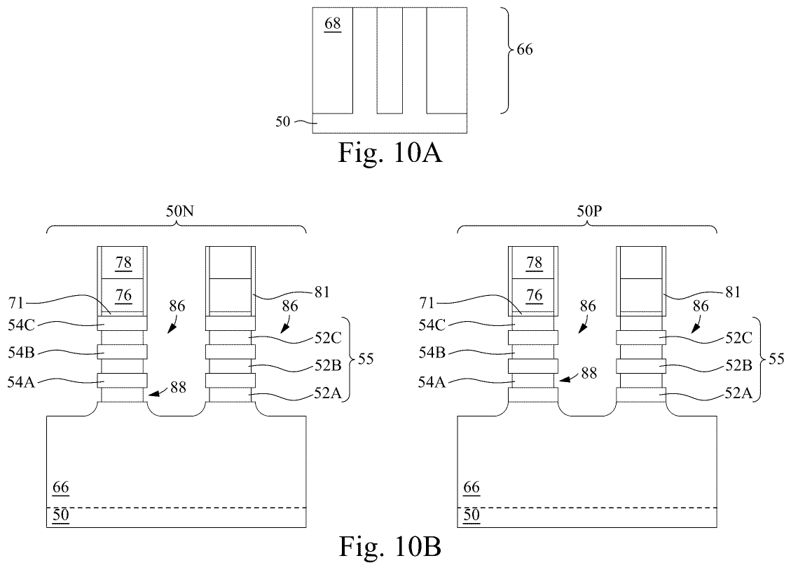

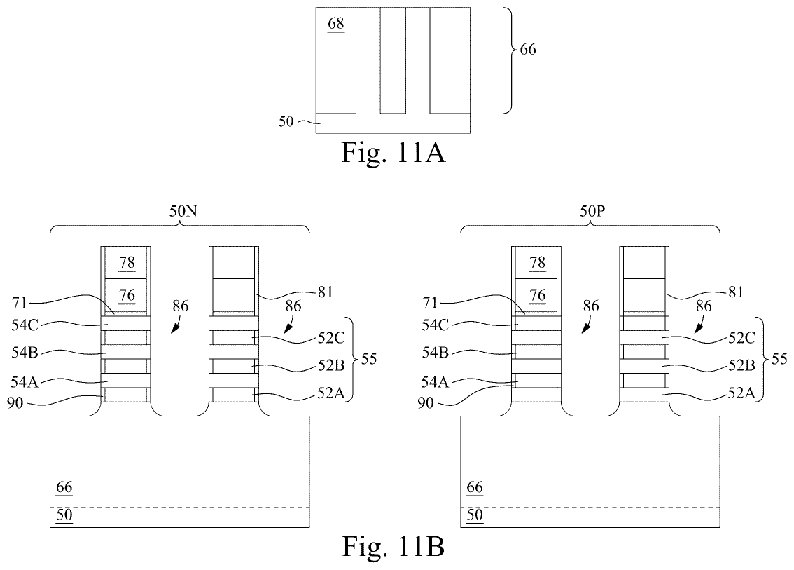

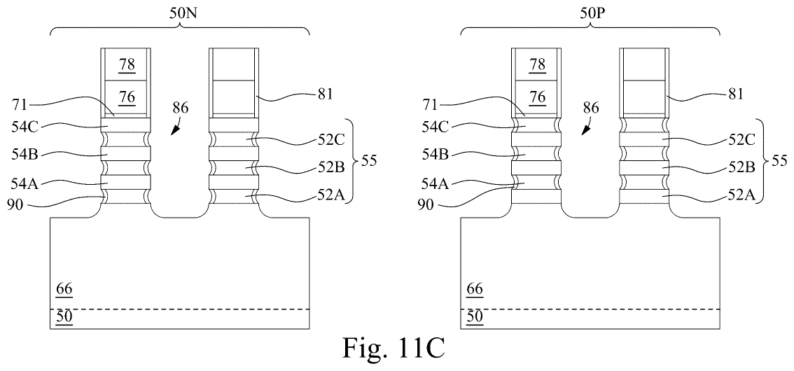

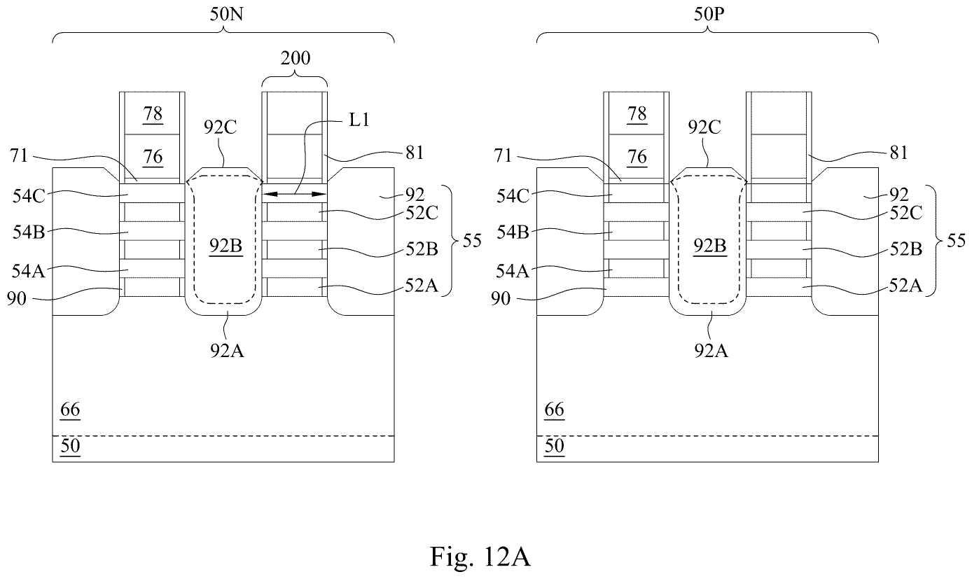

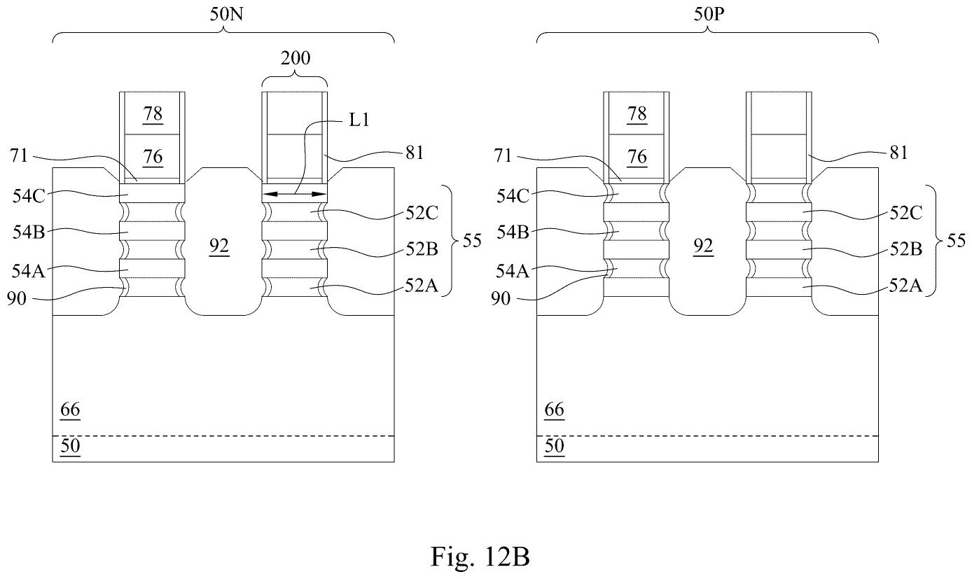

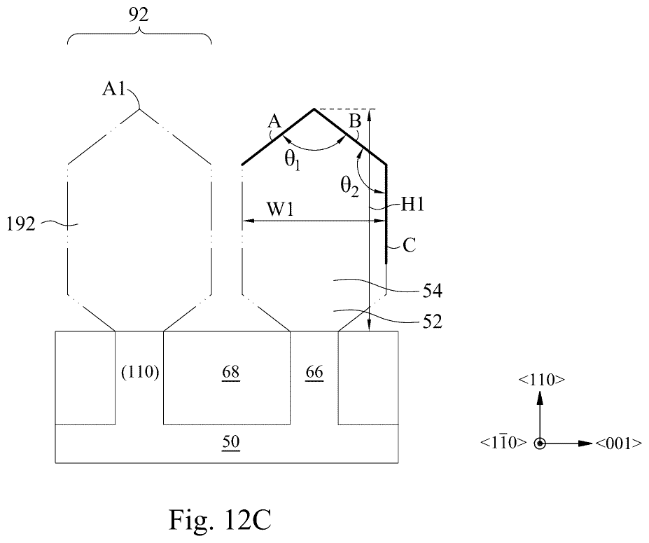

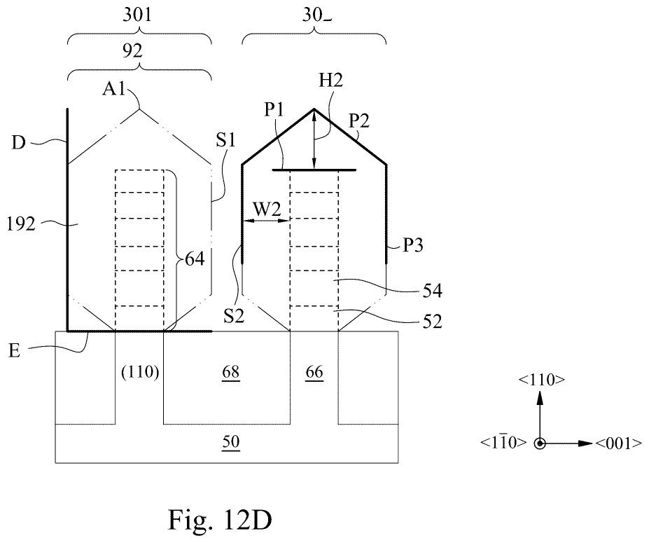

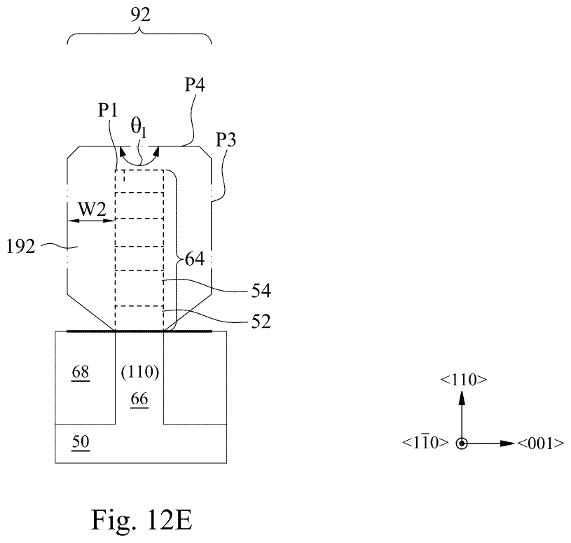

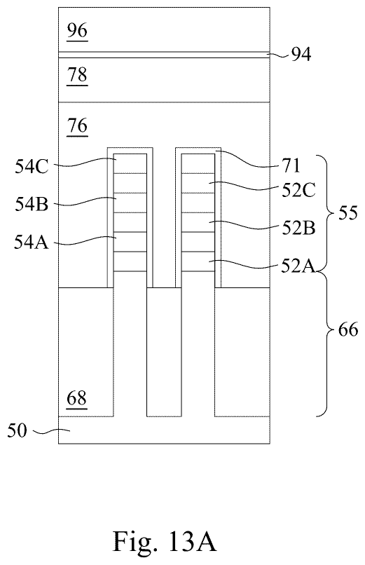

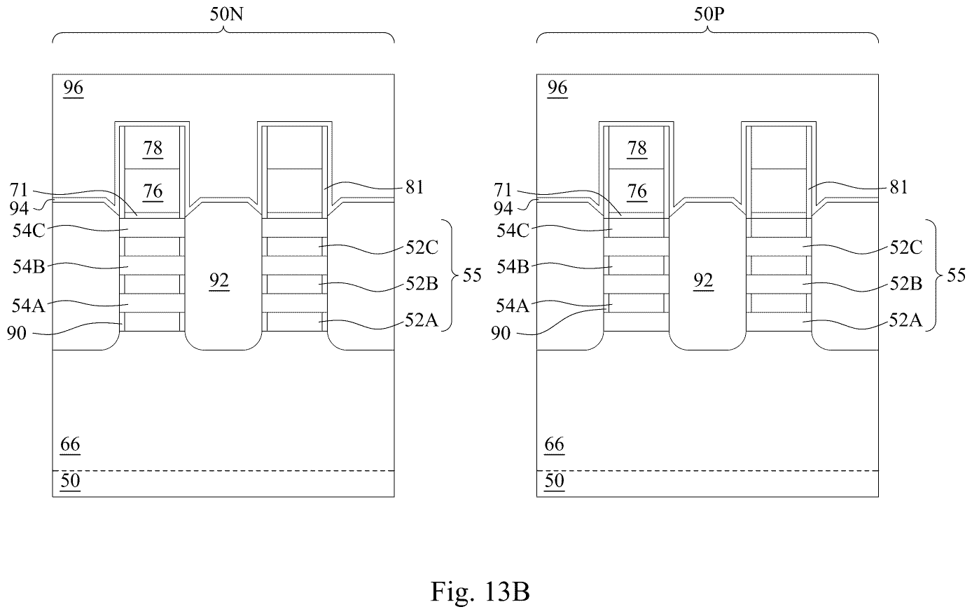

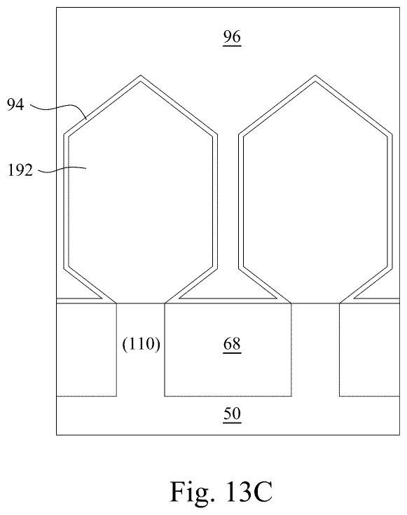

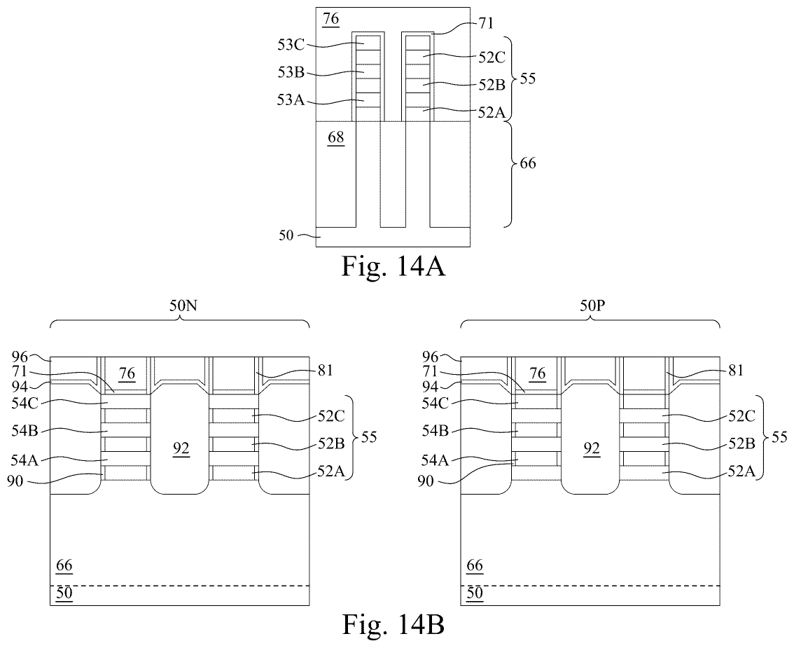

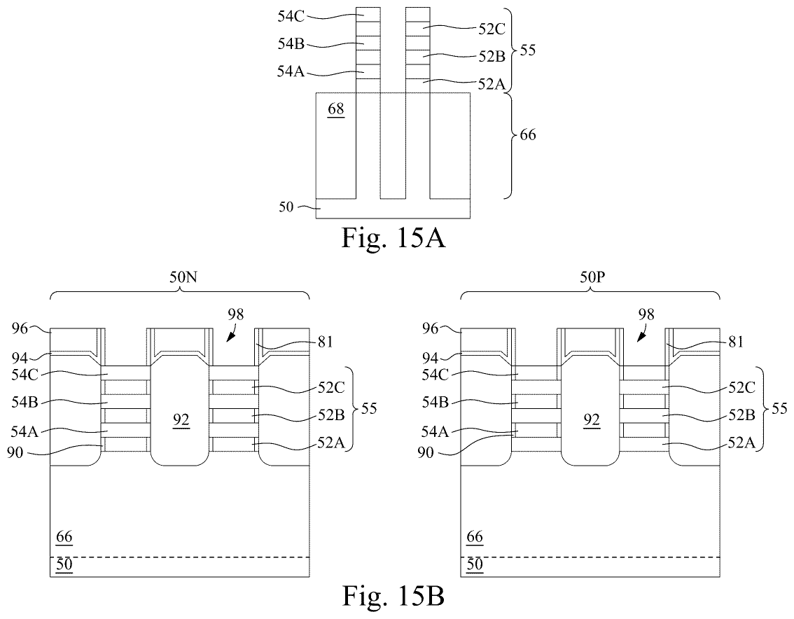

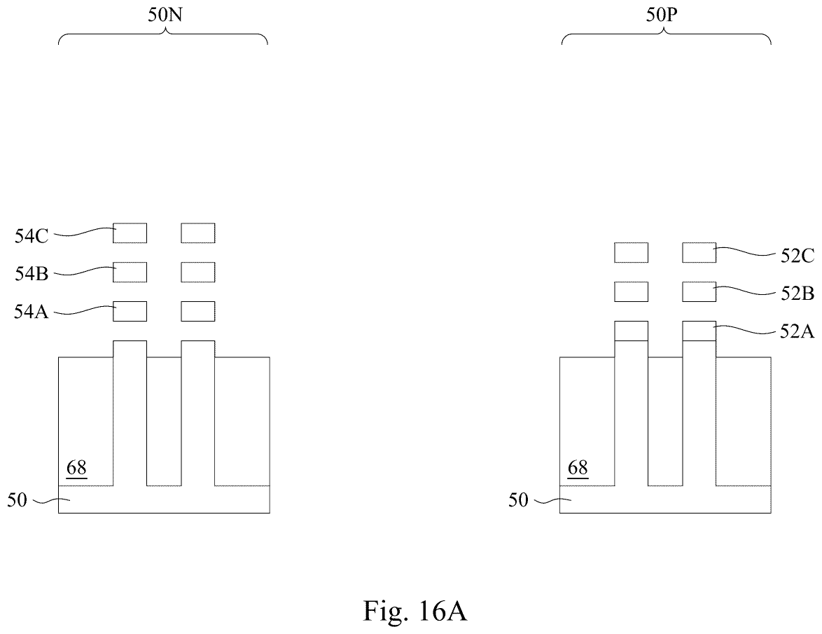

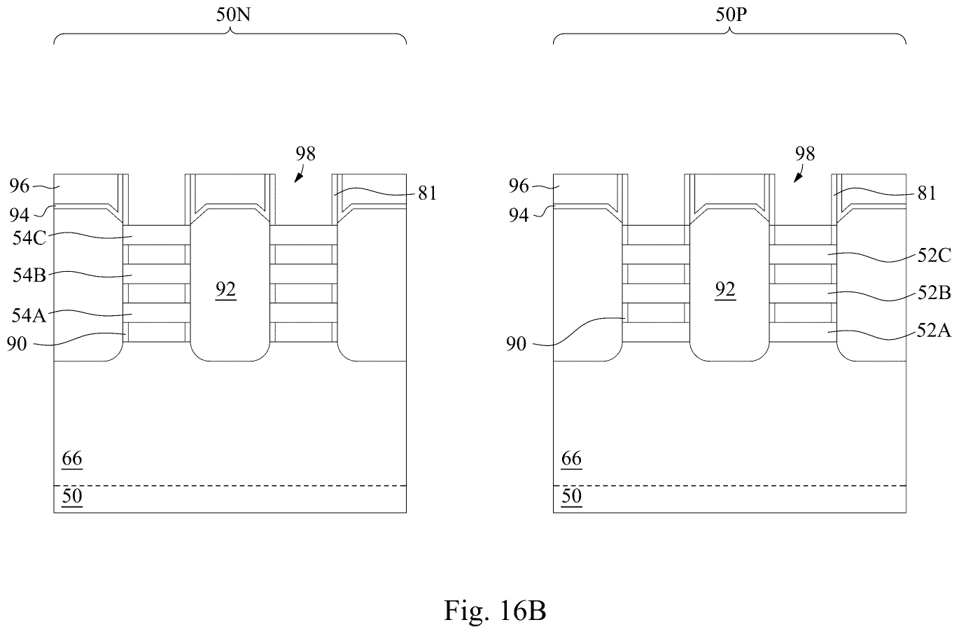

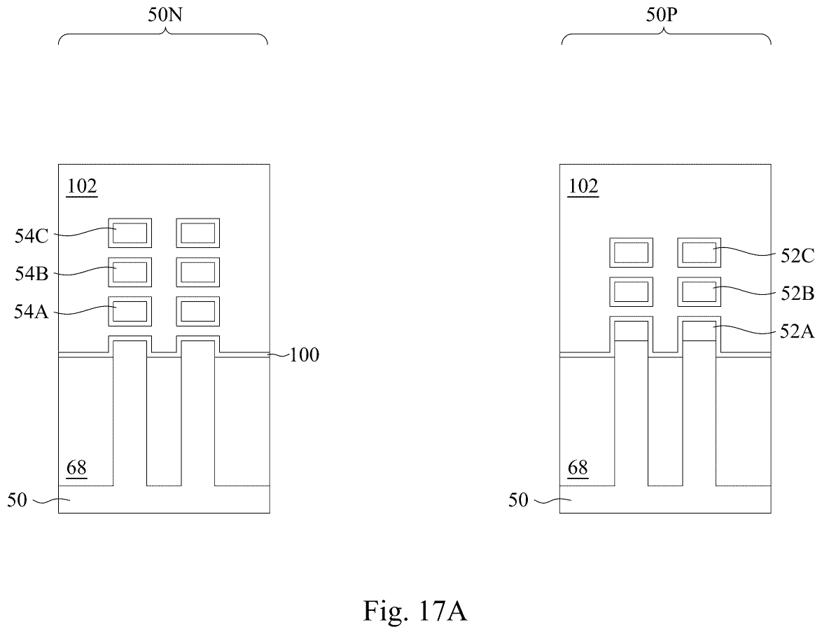

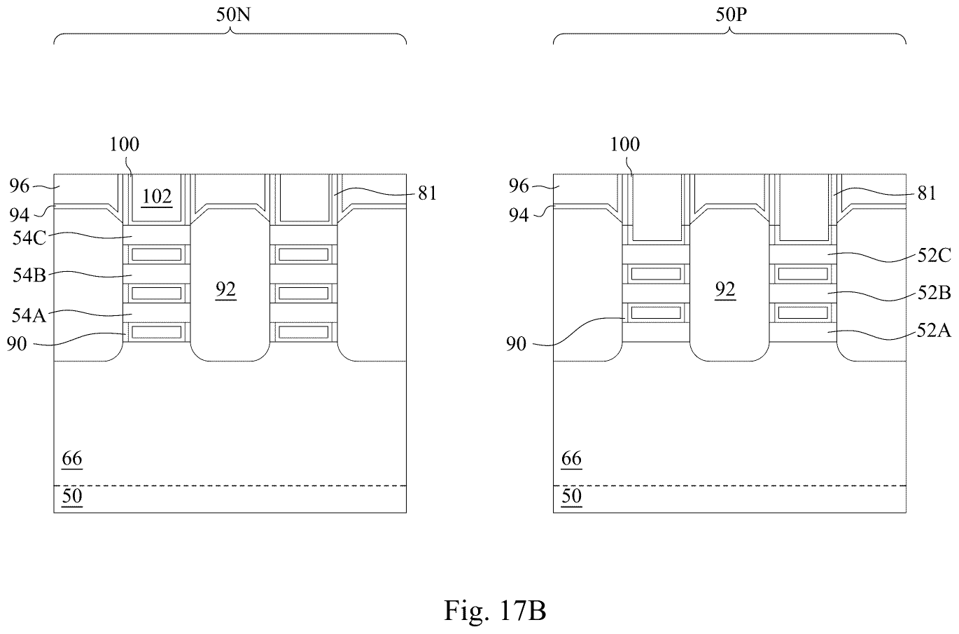

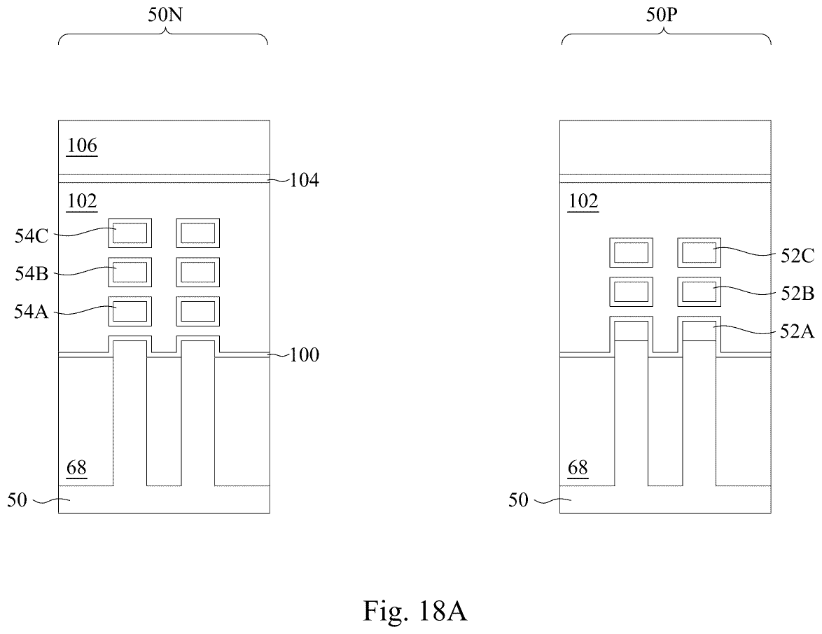

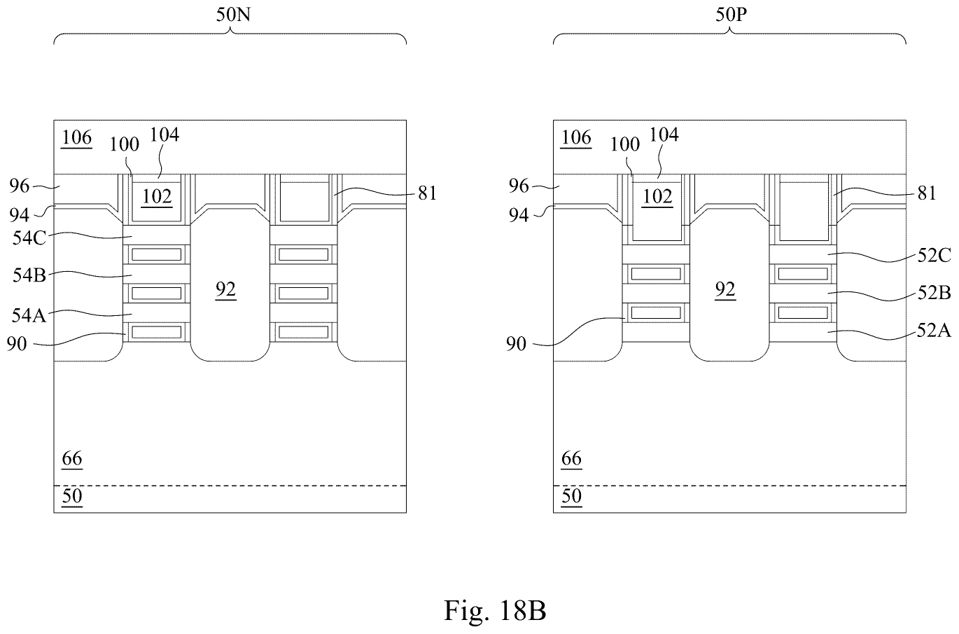

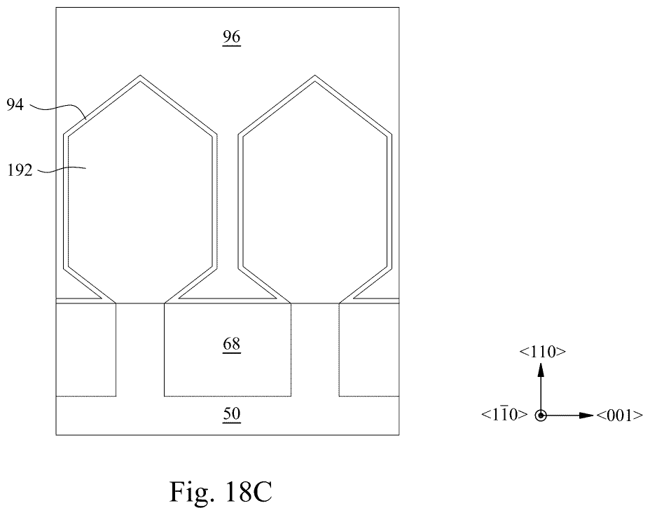

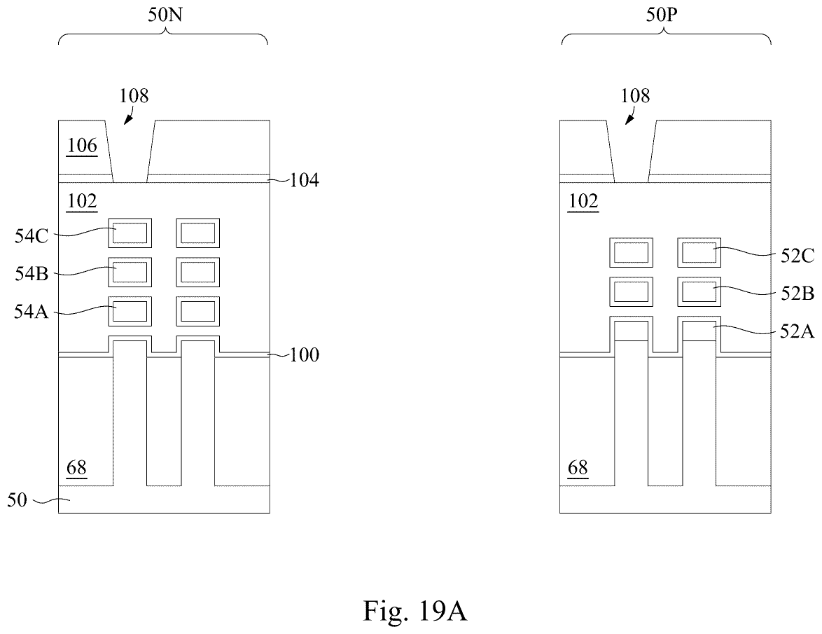

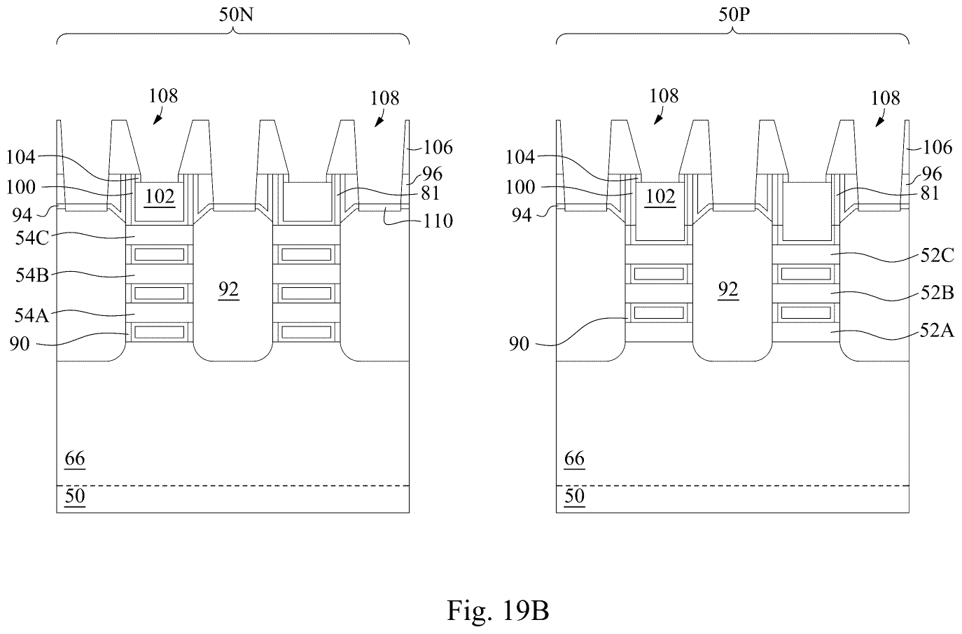

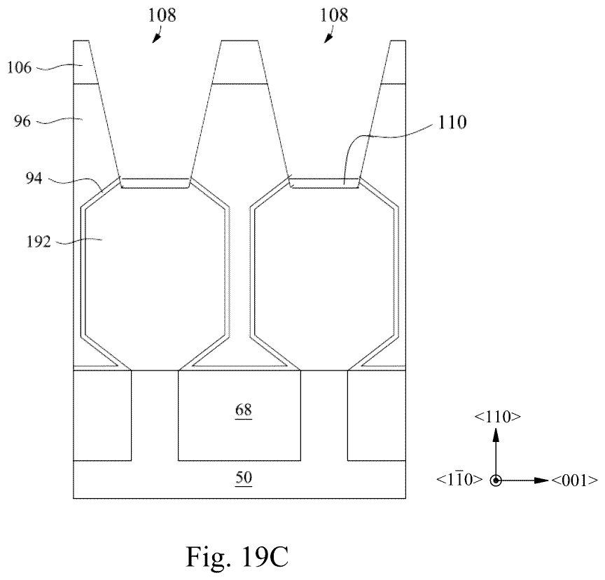

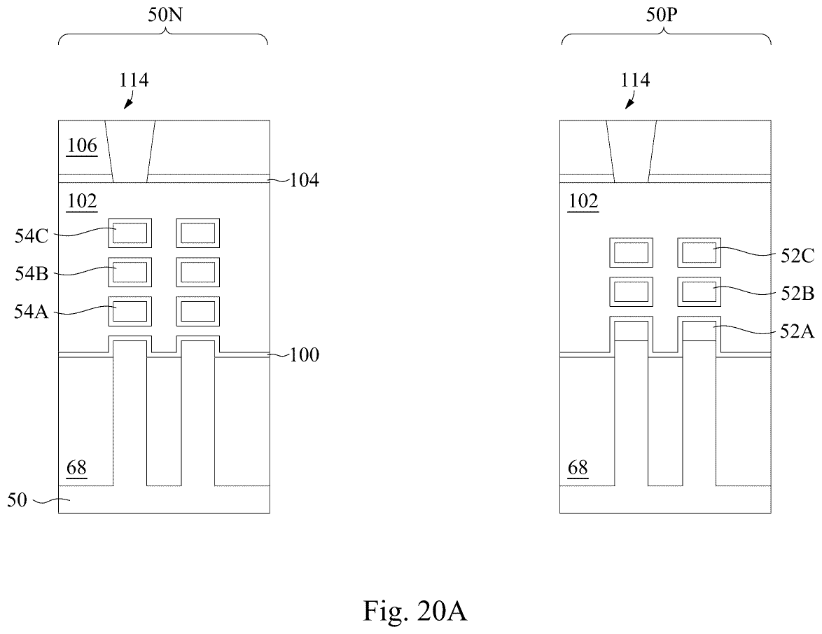

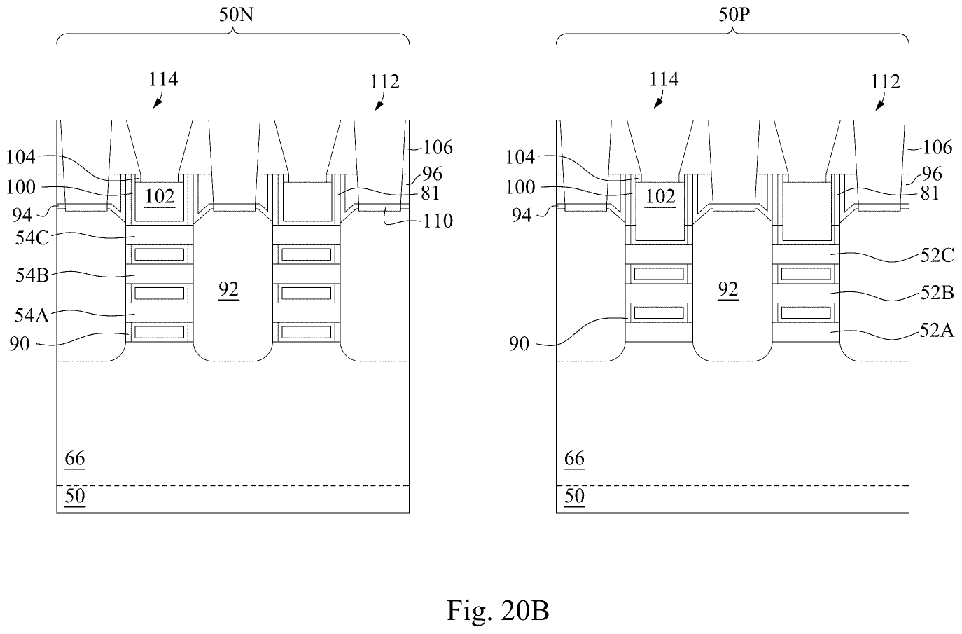

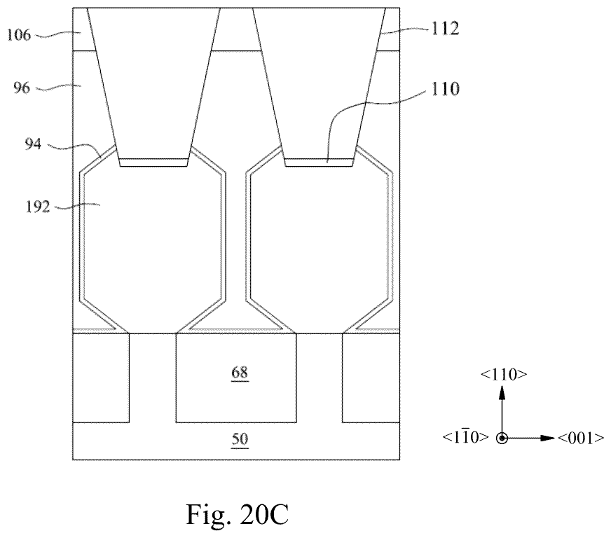

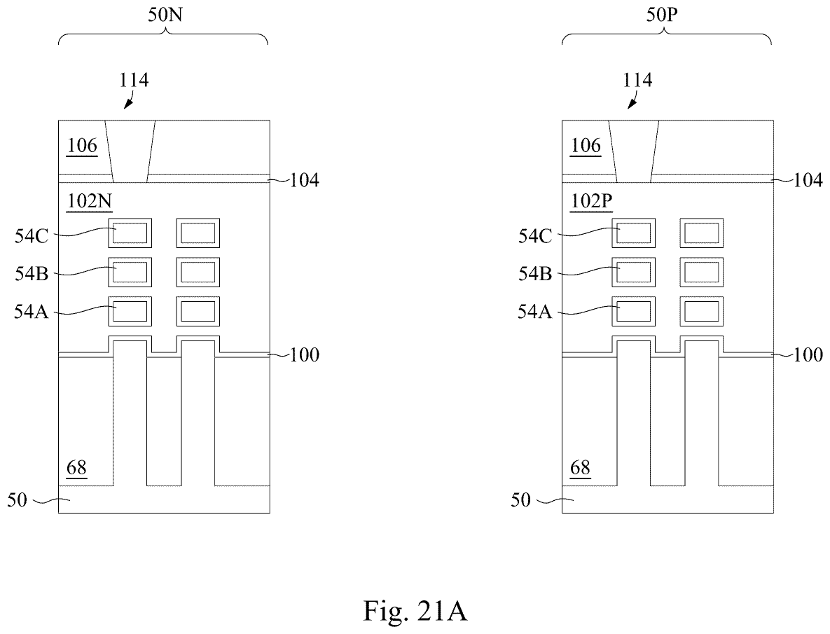

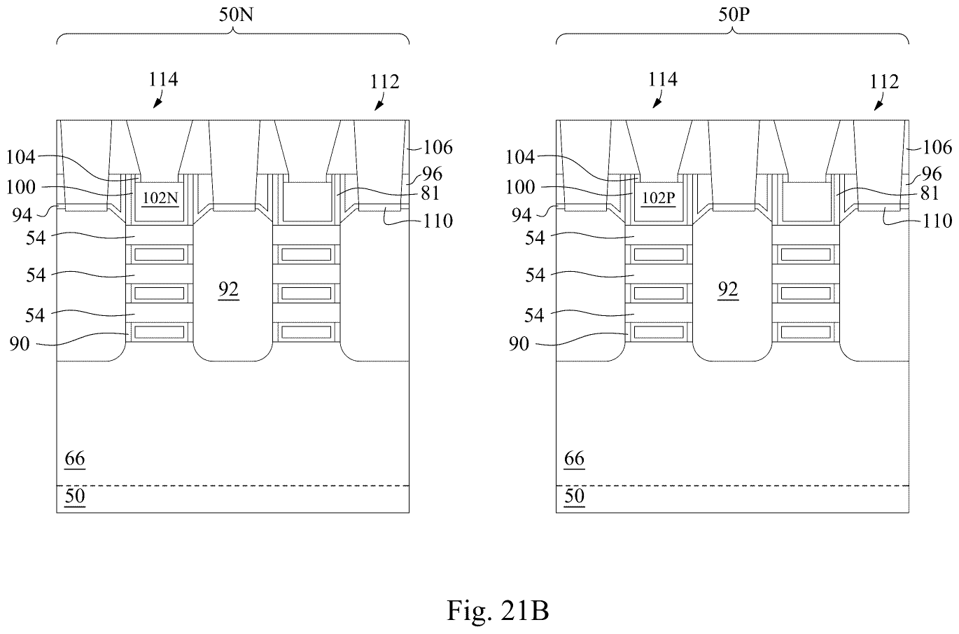

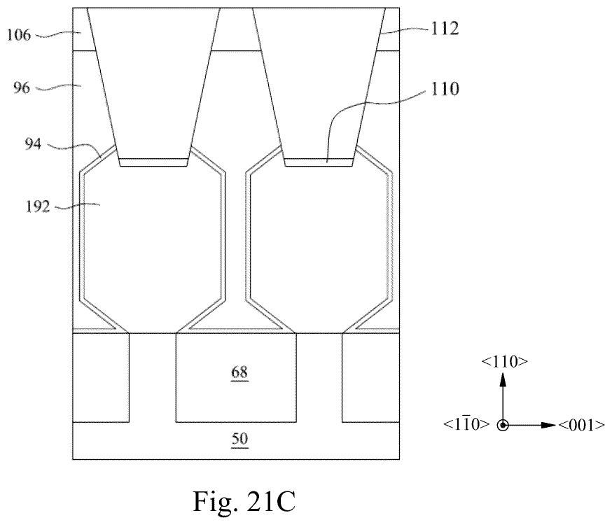

FIGS. 2 through 21C are cross-sectional views of intermediate stages in the manufacturing of nano-FETs, in accordance with some embodiments. FIGS. 2 through 5, 6A, 13A, 14A, 15A, 16A, 17A, 18A, 19A, 20A, and 21A illustrate reference cross-section A-A′ illustrated in FIG. 1. FIGS. 6B, 7B, 8B, 9B, 10B, 11B, 11C, 12A, 12B, 13B, 14B, 15B, 16B, 17B, 18B, 19B, 20B, and 21B illustrate reference cross-section B-B′ illustrated in FIG. 1. FIGS. 7A, 8A, 9A, 10A, 11A, 12C, 12D, 12E, 13C, 18C, 19C, 20C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, the semiconductor material of the substrate 50, e.g., bulk substrate or upper semiconductor material layer of an SOI substrate, has a (110) crystalline orientation. In some examples, the semiconductor material of the substrate 50 is silicon (Si) having a (110) crystalline orientation.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or another semiconductor material) and be formed simultaneously. FIGS. 21A, 21B, and 21C illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

In some embodiments, the epitaxially grown material for the first semiconductor layers 51 (and the subsequently epitaxially grown second semiconductor layers 53) are epitaxially grown on a semiconductor surface having a (110) crystalline orientation (such as a substrate 50 composed of silicon (Si) having a (110) crystalline orientation). Therefore, the upper surfaces of the epitaxially grown first semiconductor layers 51 (and the subsequently epitaxially grown second semiconductor layers 53) likewise have a (110) crystalline orientation.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

Further in FIG. 2, appropriate wells (not separately illustrated) may be formed in the first semiconductor layers 51, the second semiconductor layers 53, and/or the substrate 50. In embodiments with different well types, different implant steps for the n-type region 50N and the p-type region 50P may be achieved using a photoresist or other masks (not separately illustrated). For example, a photoresist may be formed over structures in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the structures in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the implantation process may be performed on the substrate 50 prior to forming the first semiconductor layers 51 and the second semiconductor layers 53. Subsequently, the grown materials of the first semiconductor layers 51 and/or the semiconductor layers 53 may be in situ doped during growth. Alternatively, the implantation process may be performed on one or more of the first semiconductor layers 51 and/or the second semiconductor layers 53.

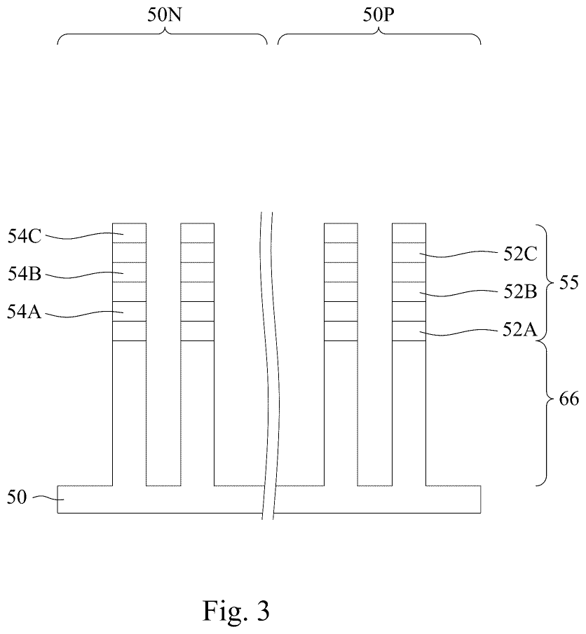

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

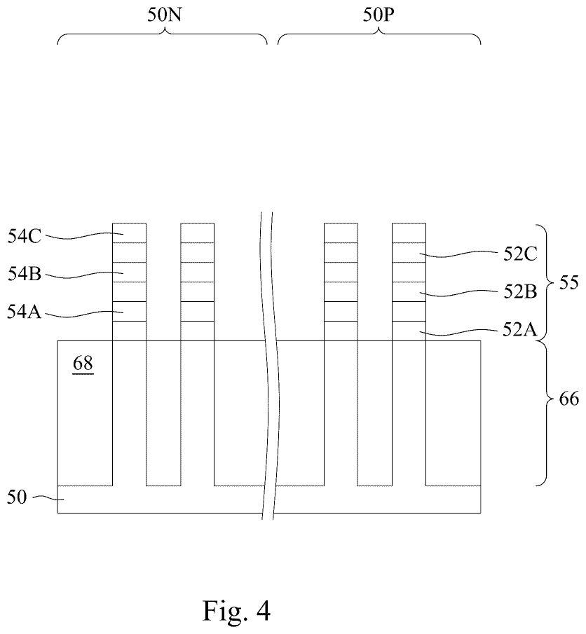

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

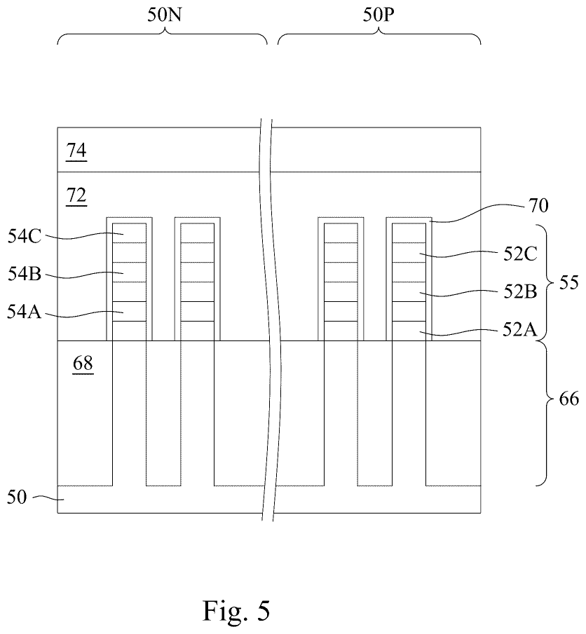

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment devices. FIGS. 7A, 8A, 9A, 10A, 11A, 12C, 12D, 12E, 13A, 13C, 14A, and 15A illustrate features in either the regions 50N or the regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. The dummy gates 76 and the dummy gate dielectric 71 may provide a sacrificial gate structure, which is later replaced with a function gate structure.

In FIGS. 7A and 7B, a first spacer layer 80 and a second spacer layer 82 are formed over the structures illustrated in FIGS. 6A and 6B, respectively. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

In FIGS. 8A and 8B, the first spacer layer 80 and the second spacer layer 82 are etched to form first spacers 81. In some embodiments, the first spacers 81 can act to protect sidewalls of the fins 66 and/or nanostructure 55 during subsequent processing. The first spacer layer 80 may be etched using a suitable etching process, such as an isotropic etching process (e.g., a wet etching process), an anisotropic etching process (e.g., a dry etching process), or the like.

As illustrated in FIG. 8A, the first spacers 81 are disposed on sidewalls of the fins 66 and/or nanostructures 55. As illustrated in FIG. 8B, in some embodiments, the second spacer layer may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. It is noted that the above disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type and p-type devices may be formed using different structures and steps.

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 56 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A-12E) by subsequent etching processes, such as etching processes used to form gate structures.

In FIGS. 12A-12E, epitaxial source/drain regions 92 are formed. In some embodiments, the epitaxial growth process for forming the epitaxial source/drain regions 92 can control the profile of epitaxially deposited material. In some embodiments, the epitaxial growth process controls the shape of the profile for epitaxially deposited material on a (110) substrate to avoid merging of adjacently positioned source/drain regions, particularly in the p-type region 50P. It is noted that the profile of the epitaxial source/drain regions 92 in the n-type region 50N may have a profile that is the same as the profile as the epitaxial source/drain regions 92 in the p-type region 50P, or the profile of the epitaxial source/drain regions 92 in the n-type region 50N may have a profile that is different from the profile as the epitaxial source/drain regions 92 in the p-type region 50P.

In some embodiments, the source/drain regions 92 may exert stress on the second nanostructures 54 in the n-type region 50N and on the first nanostructures 52 in the p-type region 50P, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

In some embodiments, the methods and structures of the present disclosure can control the profile of epitaxially deposited material, in which the profile can be controlled to be vertically flat or slightly tilted on the source/drain sidewalls to prevent merging of the epitaxial material 192 for the epitaxial source/drain regions 92 of p-type semiconductor devices. For example, in some embodiments, the PFET-to-PFET distance of the epitaxial material 192 for the epitaxial source/drain regions 92 can be controlled by orientating the device on a (110) substrate so that a specific (001) crystal plane is on the source/drain sidewalls.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon, silicon germanium, boron doped silicon germanium, silicon boride, or the like, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The (110) orientation of the substrate 50, as well as the epitaxially formed first nanostructures 52 and second nanostructures 54 that ultimately provide the channel regions of the p-type devices being formed within the p-type regions 50P will exhibit higher hole mobility when compared to other crystal orientations. A higher hole mobility means that holes (positive charge carriers) can move more freely through the material when the crystal is oriented along the (110) plane, which leads to improved performance in p-channel transistors. Applying strain, e.g., compressive strain, along the (110) direction can further enhance hole mobility.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth. In some embodiments, the first spacers 81 may cover portions of the sidewalls of the nanostructures 55 blocking epitaxial growth.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12B illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 12B, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

Referring to FIGS. 12A and 12B, the epitaxial source/drain regions 92 are formed on opposing sides of a channel portion 200 of the nanostructure stack, in which the length L1 of the channel portion is the distance between the epitaxial source/drain regions 92.

Referring to FIGS. 12C-12E, the profile for the epitaxial material 192 that provides the epitaxial source/drain regions 92 (also referred to as the source/drain epitaxial (EPI) profile, may be controlled to be vertically flat or slightly tilted on the side crystal planes P3 of the epitaxial material 192 (see FIG. 12D). FIGS. 12C-12E illustrates a cross-sectional view of the epitaxial source/drain regions 92 along cross-section C-C′ (see FIG. 1). In the cross-sections depicted in FIGS. 12E and 12D, the position of the multi-layered stack 64 of the first nanostructures 52 and the second nanostructures 54 is depicted in ghost to illustrate the positioning of the top crystalline planes P2 and side crystalline planes P3 for the epitaxial source/drain regions 92 relative to the second nanostructures 54 of the device. The crystalline orientations depicted in FIGS. 12C-12E are determined by the <11̅0> zone axis. Referring to FIGS. 12C-12E and due to the (110) orientation of the substrate 50, the <110> axis extends vertically, whereas the <001> axis extends horizontally. The <110> axis may be referred to as the axis corresponding to the height of the second nanostructures 54 (e.g., the channel regions), whereas the <001> axis may be referred to as the axis corresponding to the width of the second nanostructures 54 (e.g., the channel regions). The <11̅0> zone axis is defined as the axis going into and out of the page, which corresponds to the length L1 of the channel portion of the nanostructure stack (as depicted in FIGS. 12A-12B).

Referring to FIGS. 12C and 12D, in some embodiments, when viewed from the cross-section depicted in FIGS. 12C and 12D, the profile for the epitaxial source/drain regions 92 has six sides (has a hexagonal geometry), in which the top crystal planes P2 intersect at the apex A1, and the sides of the epitaxial source/drain regions 92 are provided by side crystal planes p3 orientated to avoid merging of the source/drain material of adjacent devices. In some embodiments, the shape of the epitaxial source/drain regions 92 results from epitaxial growth of a semiconductor material (e.g., the epitaxial material 192) on a (110) crystal plane surface (e.g., surfaces of the fins 66/substrate 50). As a result, the FET-to-FET distance of epitaxial material 192 of the source/drain regions 92 can be controlled by orientating the sidewall surface to correspond to the (001) crystal plane. More particularly, in some embodiments, the source/drain (S/D) epitaxial (EPI) profile can be controlled to include sidewall crystal planes P3 that are vertically flat or slightly tilted. For example, “vertically flat” surfaces may generally be along the plane parallel to the side crystal plane P3 that corresponds to the sidewall of the epitaxial source/drain regions 92 intersects with plane that is parallel to the upper surface of the fins 66 (as well as the plane parallel to the upper surface of the substrate 50) by a perpendicular angle. The vertically flat sidewall minimizes horizontal growth of the epitaxial source/drain regions 92 during the epitaxial growth process, which substantially reduces or eliminates the incidence of merging of the epitaxial material 192 for the epitaxial source/drain regions 92 of adjacently positioned devices. The side crystal plane P3 that corresponds to the sidewall of the epitaxial source/drain regions 92 is {001}.

For purposes of comparison, a similarly epitaxially formed material on a (100) crystalline surface would have a pentagon shaped side cross-sectional geometry. The pentagonal geometry of epitaxial material grown on a (100) surface has an angular shape {111} side crystal plane (sidewall). In comparison to a vertically flat sidewall, a sidewall defined by an angular shape is susceptible to horizontal growth that can result in the merging of the epitaxial material 192 for the source/drain regions of adjacently positioned devices. The source/drain epitaxial profile on the (110) semiconductor surface is hexagonal and provides a flat (oo1) side crystal plane P3 for more controlled PFET-merge windows.

Referring to FIG. 12C, the tallest point for the epitaxial source/drain regions 92 may terminate at an apex A1. In some embodiments, the height H1 measured from the upper surface of the fin 66 to the upper surface of the epitaxial source/drain regions 92 at the apex A1 may range from 35 nm to 70 nm. In one example, the height H1 measured from the upper surface of the fin 66 to the upper surface of the epitaxial source/drain regions 92 at the apex A1 may range from 40 nm to 65 nm. In some embodiments, the width W1 for the epitaxial material 192 of the epitaxial source/drain regions 92 may range from 25 nm t0 85 nm. In some examples, the width W1 for the epitaxial material 192 of the epitaxial source/drain regions 92 may range from 30 nm to 80 nm. In some embodiments, the width W2 of the epitaxial source/drain regions 92 between source/drain sidewalls is in a direction perpendicular to the length L1 (depicted in FIGS. 12A and 12B) of the channel portion between the epitaxial source/drain regions 92.

Still referring to FIG. 12C, the top surfaces A, B of the epitaxial material 192 having the hexagonal profile intersect at the apex A1 at an apex angle θ₁ between that may range from 95° to 180°. In an embodiment, the apex angle θ₁ ranges from 105° to 175°. In one example, the apex angle θ₁ is equal to 120°. In some embodiments, a transition angle θ₂ is between the top surfaces A, B of the epitaxial material 192 and the sidewall surface C of the epitaxial material 192. The transition angle θ₂ may range from 105 degrees to 175°. In some embodiments, the transition angle θ₂ may range from 115° to 125°. In one example, the transition angle θ₂ is equal to 120°. A transition angle θ₂ that is equal to 120° provides a sidewall including side crystal planes P3 that are vertically flat. The “slightly tilted” sidewall may have a transition angle θ₂ that ranges from 105° to 119°, or a transition angle θ₂ that ranges from 121° to 180°, which may be achieved by controlling the temperature (e.g., in the ranges described above) during the processes used to form the epitaxial material 192.

FIG. 12D illustrates the different crystal planes P2, P3 for the upper surfaces and sidewall surfaces of the epitaxial material 192 for the epitaxial source/drain regions 92. The upper surfaces of the epitaxial material 192 for the source/drain regions 92 may have a family of crystal planes P2 equivalent to {111}. The sidewall surfaces of the epitaxial material 192 for the source/drain regions 92 may have a family of crystal planes P3 equivalent to {001}. In some embodiments, the (001) crystal plane orientation for the sidewalls of the epitaxial material 192 results from epitaxially growth of the epitaxial material 192 on a semiconductor surface having a (110) crystal plane orientation, such as the fin 66 or the second nanostructure 54. In some embodiments, {111} crystal plane orientations for the upper surfaces of the epitaxial material 192 for the source/drain regions 92 merge into the apex A1. FIG. 12D further illustrates the crystal plane P1 for the upper surfaces of the second nanostructures 54 (shown in ghost). The upper surfaces of the second nanostructures 54 may have a family of crystal planes P1 equivalent to {110}.

The epitaxial material 192 that provides the S/D EPI profile on the (110) semiconductor surface is hexagonal and provides sidewalls that are flat on a (oo1) side crystal plane P3, which limits horizontal growth during the epitaxial deposition process. FIG. 12D illustrates the lateral growth thickness W2 for the epitaxial material 192 that results from the epitaxial growth process on the (110) semiconductor surface. The lateral growth thickness W2 is measured from the sidewall of the stack of the first nanostructures 52 and the second nanostructures 54. In some embodiments, the lateral growth thickness W2 may range from 2 nm to 8 nm. The sidewall face of the epitaxial source/drain regions 92 is parallel to a first plane D, and an upper surface of the fin 66 (e.g., fin portion 66 of the substrate 50) is parallel to a second plane E, wherein the first plane D is perpendicular to the second plane E.

The limited horizontal growth for the epitaxial material 192 advantageously provides for increased controllability of the distance between adjacent PFET type devices without merging of the epitaxial source/drain regions 92. For example, a first sidewall face S1 for the epitaxial source/drain regions 92 of a first device 301 can be positioned adjacent to and separate from the second sidewall face S2 for the epitaxial source/drain regions 92 of a second device 302, as illustrated in FIG. 12D.

FIG. 12D also illustrates the raise height H2 for the epitaxial material. The raise height H2 is the height of the epitaxial material 192 that is grown, as measured from the upper surface of the stack of the first nanostructures 52 and the second nanostructures 54 to the apex A1. The raise height H2 may range from 6 nm to 15 nm. The raise height H2 and the lateral growth thickness W2 provide a raise height to lateral growth thickness ratio (H2/W2) that ranges from 0.8 to 3.0. The raise height to lateral growth thickness ratio provided by the methods described herein is a characteristics of a method for providing epitaxial source/drain regions 92 having a high aspect ratio, and wide tuning range.

In addition to the selection of a substrate 50 providing a (110) crystalline orientation surface as a growth deposition surface, the epitaxial growth process for forming the epitaxial material 192 of the epitaxial source/drain regions 92 may include deposition pressures and temperatures that facilitate the growth of epitaxial material 192 as depicted in FIGS. 12C-12E.

In an embodiment, the epitaxial growth process for forming the epitaxial material 192 for the epitaxial source/drain regions 92 doped to a p-type conductivity may include an epitaxial growth temperature ranging from 400 °C to 850 °C, and a pressure ranging from 4 torr to 300 torr. The flow rates for the processing gasses of the epitaxial growth process may range from 20 sccm (standard cubic centimeters per minute) to 150 sccm. It has been observed that by controlling the temperature, pressure, and/or flow rates of the epitaxial growth process, the epitaxial material 192 having the profile described herein can be formed.

In some embodiments, the processes gasses for the epitaxial growth process for forming the epitaxial material 192 of the epitaxial source/drain regions 92 may include silane (SiH₄), dichlorosilane (Cl₂SiH₂) (DCS), hydrogen chloride (HCl), germane (GeH₄), borane (BH₃), Boron trichloride (BCl₃) and combinations thereof. It is noted that the above process gasses are provided for illustrative purposes only and it is not intended that the present disclosure be limited to only the above examples.

For example, a number of different sources may be used for the deposition of the epitaxial material 192 that forms the epitaxial source/drain regions 92. In some embodiments, in which the epitaxial material 192 that forms the epitaxial source/drain regions 92 is composed of silicon (Si), the silicon gas source for epitaxial deposition may be selected from the group consisting of hexachlorodisilane (Si₂Cl₆), tetrachlorosilane (SiCl₄), dichlorosilane (Cl₂SiH₂), trichlorosilane (Cl₃SiH), methylsilane ((CH₃)SiH₃), dimethylsilane ((CH₃)₂SiH₂), ethylsilane ((CH₃CH₂)SiH₃), methyldisilane ((CH₃)Si2H₅), dimethyldisilane ((CH₃)₂Si2H₄), hexamethyldisilane ((CH₃)₆Si₂) and combinations thereof.

For example, in some embodiments, in which the epitaxial material 192 that forms the epitaxial source/drain regions 92 is composed of germanium (Ge), the germanium gas source for epitaxial deposition may be selected from the group consisting of germane (GeH₄), digermane (Ge₂H₆), halogermane, dichlorogermane, trichlorogermane, tetrachlorogermane and combinations thereof.

In some embodiments, in which the epitaxial material 192 that forms the epitaxial source/drain regions 92 is composed of silicon germanium (SiGe), the silicon (Si) sources for epitaxial deposition may be selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof, and the germanium gas sources may be selected from the group consisting of germane, digermane, halogermane, dichlorogermane, trichlorogermane, tetrachlorogermane and combinations thereof.

In some embodiments, the dopant that provides the conductivity type for the epitaxial source/drain regions 92 is provided in situ. In situ doping is a technique that involves the incorporation of dopants into a precursor lattice, e.g., provided by the silicon (Si) and/or germanium (Ge) during the synthesis process, e.g., the epitaxial growth process. In some embodiments, the dopant gas source for doping the epitaxial material 192 with a p-type dopant, e.g., boron, may be provided by diborane (B₂H₆). However, borane (BH₃) and/or boron trichloride (BCl₃) may also be used to provide the p-type dopant source. Although, the epitaxial deposition process has been described for applications, in which the PFET to PFET distance may be controlled, and merger of the epitaxial source/drain regions is avoided for p-type conductivity doped source/drain regions, in some embodiments, the epitaxial source/drain regions 92 may be doped with an n-type conductivity type dopant. In some embodiments, the dopant gas source for doping the epitaxial material 192 with an n-type dopant, e.g., arsenic and/or phosphorus, may include arsine (AsH₃), phosphine (PH₃) and alkylphosphines.

In some embodiments, the aforementioned process gasses can be transported to a process chamber for epitaxial growth in combination with a carrier gas, such as a hydrogen (H₂) carrier gas. In an embodiment, the carrier gas has a flow rate ranging from 1 slm (standard liters per minute) to 100 slm. In an embodiment, the carrier gas is 75-90% of the total gas flows being employed in the epitaxial growth process.

FIG. 12E illustrates another embodiment of the present disclosure, in which the upper surface of the epitaxial material 192 for the epitaxial source/drain regions 92 is flat. The upper surface of the epitaxial material 192 may be controlled by adjusting the temperature during the epitaxial growth process. For example, when the temperature of the epitaxial growth process is limited to 700 °C or less, the upper surface of the epitaxial material 192 may have an apex A1, as depicted in FIGS. 12C-12D. However, in some embodiments, when the temperature is increased to greater than 700 °C, the apex A1 may be removed from the upper surface of the epitaxial material 192. For example, when the epitaxial deposition temperature ranges from 700 °C to 850 °C, the apex angle θ₁ increases to 180°, which results in an upper surface of the epitaxial material 192 being flat. The upper surfaces of the epitaxial material 192 in the embodiment of FIG. 12E may have a family of crystal planes P4 equivalent to {110}. Similar to the embodiments described with reference to FIGS. 12A-12E, the epitaxial material 192 includes a flat sidewall orientated along the (oo1) side crystal plane P3 (e.g., the family of crystal planes {001}) that limits horizontal growth of the epitaxial material 192 during the epitaxial deposition process. Also, the upper surfaces of the second nanostructures 54 may have a family of crystal planes P1 equivalent to {110}. Similar to the embodiments described above with reference to FIGS. 12A-12E, the lateral growth thickness W2 for the epitaxial material 192 depicted in FIG. 12E is effectively limited by the geometry of the epitaxial material 192 that is epitaxially grown on a (110) crystal plane semiconductor surface, which results in a sidewall that is vertically flat and having a side crystal plane P3 with in family {001}.

In yet another embodiment, the upper surface of the epitaxial material 192 that provides the epitaxial source/drain regions 92 may be adjusted to be flat by increasing the germanium (Ge) content in the epitaxial source/drain regions 92. For example, when the germanium (Ge) content of the epitaxial material 192 is less than 50%, the upper surface of the epitaxial material 192 may have an apex A1, as depicted in FIGS. 12C-12D. However, in some embodiments, when the germanium content is increased to greater than 50%, the apex A1 may be removed from the upper surface of the epitaxial material 192. For example, when the germanium (Ge) content ranges from 50% to 80%, the apex angle θ₁ increases to 180°, which results in an upper surface of the epitaxial material 192 being flat. It is noted that the remaining figures illustrate forming contacts to the epitaxial material 192 depicted in FIGS. 12C-12E; however, contacts may be formed to the epitaxial material 192 depicted in FIG. 12E using similar methods.

In FIGS. 13A-13C, a first interlayer dielectric (ILD) 96 is deposited over the structure illustrated in FIGS. 12A-12E. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 14A-14C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 15A and 15B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 71 may then be removed after the removal of the dummy gates 76.

In FIGS. 16A and 16B, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 68 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P. It is noted that the above example is only one example of the compositions for the second nanostructures in the p-type region 50P. For example, the second nanostructures 54 in the p-type region 50P may be silicon (Si).

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 21A, 21B, and 21C illustrate a structure resulting from such embodiments where the channel regions in both the p-type region 50P and the n-type region 50N are provided by the second nanostructures 54 and comprise silicon, for example. Silicon is only one example for the composition of the second nanostructures 54 for the embodiment illustrated in FIGS. 21A, 21B and 21C. In another embodiment, the composition for the second nanostructures 54 for the embodiment illustrated in FIGS. 21A, 21B and 21C may be a germanium (Ge) containing composition, such as silicon germanium (SiGe).

In FIGS. 17A and 17B, gate dielectric layers 100 and gate electrodes 102 are formed for replacement gates. The gate dielectric layers 100 and the gate electrode 102 may also be referred to as a functional gate structure. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the Like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

In FIGS. 18A-18C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 20A-20C) penetrate through the gate mask 104 to contact the top surface of the recessed gate electrodes 102.

As further illustrated by FIGS. 18A-18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 19A-19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 19B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 20A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 21A-C illustrate cross-sectional views of a device according to some alternative embodiments. FIG. 21A illustrates reference cross-section A-A′ illustrated in FIG. 1. FIG. 21B illustrates reference cross-section B-B′ illustrated in FIG. 1. FIG. 21C illustrates reference cross-section C-C′ illustrated in FIG. 1. In FIGS. 21A-C, like reference numerals indicate like elements formed by like processes as the structure of FIGS. 20A-C. However, in FIGS. 21A-C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. In another example, the second nanostructures 54, which comprise a germanium containing material, such as silicon germanium (SiGe), provide channel regions for p-type nano-FETs in the p-type region 50P and for n-type nano-FETs in the n-type region 50N. The structure of FIGS. 21A-C may be formed, for example, by removing the first nanostructures 52 from both the p-type region 50P and the n-type region 50N simultaneously; depositing the gate dielectric layers 100 and the gate electrodes 102P (e.g., gate electrode suitable for a p-type nano-FET) around the second nanostructures 54 in the p-type region 50P; and depositing the gate dielectric layers 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

Embodiments may achieve advantages. For example, in some embodiments, the methods and structures describe herein control the shape of epitaxially deposited material that is formed on semiconductor surfaces that are based on a (110) substrate to avoid merging of the epitaxial source/drain regions of adjacently positioned p-type field effect transistor (PFET) devices. In some embodiments, the epitaxial source/drain profile can be controlled to be vertically flat on their sidewall faces to prevent PFET-merge. The PFET-to-PFET distance may be controlled through configuring the epitaxial material of the source/drain regions to orientate the sidewall of the epitaxial material with a (001) crystal plane.

In some embodiments, a method includes forming a nanostructure stack on a substrate, the substrate having a (110) crystalline orientation; forming a gate structure on a channel portion of the nanostructure stack; and forming source/drain regions on opposing sides of the channel portion of the nanostructure stack, wherein a width of the source/drain regions between source/drain sidewalls is in a direction perpendicular to a length of the channel portion between the source/drain regions, the source/drain sidewalls having a sidewall face along a (001) plane. Optionally, in some embodiments, an upper surface of the source/drain regions includes a first tilted surface, a second tilted surface, and an apex, wherein the first tilted surface and the second tilted surface intersect at the apex. Optionally, in some embodiments, an apex angle at the apex between the first titled surface and the second titled surface ranges from 105 degrees to 175 degrees. Optionally, in some embodiments, a deposition temperature for forming the source/drain regions having the apex is less than 700 °C. Optionally, in some embodiments, the first tilted surface and the second tilted surface are oriented along a {111} family of planes. Optionally, in some embodiments, a transition angle is between the sidewall face and each of the first titled surface and the second titled surface, wherein the transition angle ranges from 115° to 125°. Optionally, in some embodiments, the sidewall face of the source/drain sidewalls is parallel to a first plane, and an upper surface of the substrate is parallel to a second plane, wherein the first plane is perpendicular to the second plane. Optionally, in some embodiments, an upper surface of the source/drain regions is flat. Optionally, in some embodiments, a deposition temperature for forming the upper surface of the source/drain regions being flat is greater than 700 °C.

In an embodiment, a method includes forming a first nanostructure stack on a first portion of a substrate having a (110) crystalline orientation; forming a second nanostructure stack on a second portion of the substrate having the (110) crystalline orientation; forming a first device on the first portion of the substrate, the first device comprising a first gate structure on a first portion of the first nanostructure stack, and first source/drain regions on opposing sides of the first portion of the first nanostructure stack, wherein a first width between first source/drain sidewalls of the first source/drain regions is in a direction perpendicular to a first length of the first portion of the first nanostructure stack between the first source/drain regions, the first source/drain sidewalls having a first sidewall face along a (001) plane; and forming a second device on the second portion of the substrate, the second device comprising a second gate structure on a second portion of the second nanostructure stack, and second source/drain regions on opposing sides of the second portion of the second nanostructure stack, wherein a second width between second source/drain sidewalls of the second source/drain regions is in a direction perpendicular to a second length of the second portion of the second nanostructure stack between the second source/drain regions, the second source/drain sidewalls having a second sidewall face along a (001) plane, wherein the first sidewall face of the first device is positioned adjacent to and separate from the second sidewall face of the second device. Optionally, in some embodiments, an upper surface for the first source/drain regions, the second source/drain regions or a combination of the first source/drain regions and the second source/drain regions includes an apex. Optionally, in some embodiments, an upper surface for the first source/drain regions, the second source/drain regions or a combination of the first source/drain regions and the second source/drain regions is flat. Optionally, in some embodiments, the first sidewall face is parallel to a first plane and an upper surface of the substrate is parallel to a second plane wherein the first plane is perpendicular to the second plane. Optionally, in some embodiments, the second sidewall face is parallel to a third plane, and an upper surface of the substrate is parallel to a second plane, wherein the third plane is perpendicular to the second plane.

In some embodiments, a device includes a substrate having a (110) crystalline orientation; a first device on a first portion of the substrate, the first device comprising a first nanostructure stack, a first gate structure on a first portion of the first nanostructure stack, and first source/drain regions on opposing sides of the first portion of the first nanostructure stack, wherein a first width between first source/drain sidewalls of the first source/drain regions is in a direction perpendicular to a first length of the first portion of the first nanostructure stack between the first source/drain regions, the first source/drain sidewalls having a first sidewall face along a (001) plane; and a second device on a second portion of the substrate, the second device comprising a second nanostructure stack, a second gate structure on a second portion of the second nanostructure stack, and second source/drain regions on opposing sides of the second portion of the second nanostructure stack, wherein a second width between second source/drain sidewalls of the second source/drain regions is in a direction perpendicular to a second length of the second portion of the second nanostructure stack between the second source/drain regions, the second source/drain sidewalls having a second sidewall face along a (001) plane, wherein the first sidewall face of the first device is positioned adjacent to and separate from the second sidewall face of the second device. Optionally, in some embodiments, an upper surface for the first source/drain regions, the second source/drain regions or a combination of the first source/drain regions is along a family of planes. Optionally, in some embodiments, an upper surface for the first source/drain regions, the second source/drain regions or a combination of the first source/drain regions and the second source/drain regions is along a family of planes. Optionally, in some embodiments, the first sidewall face is parallel to a first plane and an upper surface of the substrate is parallel to a second plane wherein the first plane is perpendicular to the second plane. Optionally, in some embodiments, the second sidewall face is parallel to a third plane, and an upper surface of the substrate is parallel to a second plane, wherein the third plane is perpendicular to the second plane. Optionally, in some embodiments, an upper surface for the first nanostructure stack, the second nanostructure stack or a combination is along a {110} family of planes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a nanostructure stack on a substrate, the substrate having a (110) crystalline orientation;
forming a gate structure on a channel portion of the nanostructure stack; and
forming source/drain regions on opposing sides of the channel portion of the nanostructure stack, wherein a width of the source/drain regions between source/drain sidewalls is in a direction perpendicular to a length of the channel portion between the source/drain regions, the source/drain sidewalls having a sidewall face along a (001) plane.

2. The method of claim 1, wherein an upper surface of the source/drain regions includes a first tilted surface, a second tilted surface, and an apex, wherein the first tilted surface and the second tilted surface intersect at the apex.

3. The method of claim 2, wherein an apex angle at the apex between the first titled surface and the second titled surface ranges from 105 degrees to 175 degrees.

4. The method of claim 2, wherein a deposition temperature for forming the source/drain regions having the apex is less than 700 °C.

5. The method of claim 2, wherein the first tilted surface and the second tilted surface are oriented along a {111} family of planes.

6. The method of claim 3, wherein a transition angle is between the sidewall face and each of the first titled surface and the second titled surface, wherein the transition angle ranges from 115° to 125°.

7. The method of claim 1, wherein the sidewall face of the source/drain sidewalls is parallel to a first plane, and an upper surface of the substrate is parallel to a second plane, wherein the first plane is perpendicular to the second plane.

8. The method of claim 1, wherein an upper surface of the source/drain regions is flat.

9. The method of claim 8, wherein a deposition temperature for forming the upper surface of the source/drain regions being flat is greater than 700 °C.

10. A method comprising:
forming a first nanostructure stack on a first portion of a substrate having a (110) crystalline orientation;
forming a second nanostructure stack on a second portion of the substrate having the (110) crystalline orientation;
forming a first device on the first portion of the substrate, the first device comprising a first gate structure on a first portion of the first nanostructure stack, and first source/drain regions on opposing sides of the first portion of the first nanostructure stack, wherein a first width between first source/drain sidewalls of the first source/drain regions is in a direction perpendicular to a first length of the first portion of the first nanostructure stack between the first source/drain regions, the first source/drain sidewalls having a first sidewall face along a (001) plane; and
forming a second device on the second portion of the substrate, the second device comprising a second gate structure on a second portion of the second nanostructure stack, and second source/drain regions on opposing sides of the second portion of the second nanostructure stack, wherein a second width between second source/drain sidewalls of the second source/drain regions is in a direction perpendicular to a second length of the second portion of the second nanostructure stack between the second source/drain regions, the second source/drain sidewalls having a second sidewall face along a (001) plane, wherein the first sidewall face of the first device is positioned adjacent to and separate from the second sidewall face of the second device.

11. The method of claim 10, wherein an upper surface for the first source/drain regions, the second source/drain regions or a combination of the first source/drain regions and the second source/drain regions includes an apex.

12. The method of claim 10, wherein an upper surface for the first source/drain regions, the second source/drain regions or a combination of the first source/drain regions and the second source/drain regions is flat.

13. The method of claim 10, wherein the first sidewall face is parallel to a first plane and an upper surface of the substrate is parallel to a second plane wherein the first plane is perpendicular to the second plane.

14. The method of claim 10, wherein the second sidewall face is parallel to a third plane, and an upper surface of the substrate is parallel to a second plane, wherein the third plane is perpendicular to the second plane.

15. A device comprising:
a substrate having a (110) crystalline orientation;
a first device on a first portion of the substrate, the first device comprising a first nanostructure stack, a first gate structure on a first portion of the first nanostructure stack, and first source/drain regions on opposing sides of the first portion of the first nanostructure stack, wherein a first width between first source/drain sidewalls of the first source/drain regions is in a direction perpendicular to a first length of the first portion of the first nanostructure stack between the first source/drain regions, the first source/drain sidewalls having a first sidewall face along a (001) plane; and
a second device on a second portion of the substrate, the second device comprising a second nanostructure stack, a second gate structure on a second portion of the second nanostructure stack, and second source/drain regions on opposing sides of the second portion of the second nanostructure stack, wherein a second width between second source/drain sidewalls of the second source/drain regions is in a direction perpendicular to a second length of the second portion of the second nanostructure stack between the second source/drain regions, the second source/drain sidewalls having a second sidewall face along a (001) plane, wherein the first sidewall face of the first device is positioned adjacent to and separate from the second sidewall face of the second device.

16. The device of claim 15, wherein an upper surface for the first source/drain regions, the second source/drain regions or a combination of the first source/drain regions is along a {111} family of planes.

17. The device of claim 15, wherein an upper surface for the first source/drain regions, the second source/drain regions or a combination of the first source/drain regions and the second source/drain regions is along a {110} family of planes.

18. The device of claim 15, wherein the first sidewall face is parallel to a first plane and an upper surface of the substrate is parallel to a second plane wherein the first plane is perpendicular to the second plane.

19. The device of claim 16, wherein the second sidewall face is parallel to a third plane, and an upper surface of the substrate is parallel to a second plane, wherein the third plane is perpendicular to the second plane.

20. The device of claim 16, wherein an upper surface for the first nanostructure stack, the second nanostructure stack or a combination is along a {110} family of planes.
